(19) United States
(12) Patent Application Publication
(10) Pub. No.: US 2018/0167070 A1
(43) Pub. Date: Jun. 14, 2018

(54) SHIFT REGISTER AND GATE DRIVER INCLUDING THE SAME

(71) Applicant: LG DISPLAY CO., LTD., Seoul (KR)

(72) Inventor: Nakwoo KIM, GUMI-SI (KR)

(73) Assignee: LG DISPLAY CO., LTD., Seoul (KR)

(21) Appl. No.: 15/824,667

(22) Filed: Nov. 28, 2017

(30) Foreign Application Priority Data
Dec. 13, 2016 (KR) 10-2016-0169402

(51) Int. Cl. H03K 19/017; G02F 1/1362; G09G 3/36

(52) U.S. Cl. CPC H03K 19/01742; G09G 2310/0286; G09G 3/3677; G02F 1/136286

(57) ABSTRACT

Agate driver includes a shift register including a plurality of stages. The n^{th} stage among the stages includes a buffer switching element having a gate electrode connected to a Q-node and a drain electrode to receive a first clock, a first switching element having a gate electrode to receive a second clock and a drain electrode to receive a start pulse, and a second switching element having a gate electrode to receive the second clock and a drain electrode to receive a gate high voltage, a first capacitor connected between the Q-node and a source electrode of the buffer switching element, and a second capacitor connected between the drain electrode of the first switching element and the Q-node. The number of switching elements included in the gate driver is drastically reduced, such that the numbers of clock signals and voltage signals required for driving the gate driver can be reduced.

### CROSS-REFERENCE TO RELATED APPLICATIONS

This application claims the priority of Korean Patent Application No. 10-2016-0169402 filed on Dec. 13, 2016, in the Korean Intellectual Property Office, the disclosure of which is incorporated herein by reference.

### BACKGROUND

### Technical Field

The present disclosure relates to a shift register and a gate driver including the shift register, and more particularly, to a shift register that allow a gate driver including the shift register to occupy a smaller area.

### Description of the Related Art

A flat panel display (FPD) has been employed in a variety of electronic devices such as mobile phones, tablet computers, laptop computers, televisions and monitors. Recently, FPDs include a liquid-crystal display (LCD), an organic light-emitting display (OLED), etc. Such a display device includes an array of pixels in which an image is displayed, and a driving circuit that controls the pixels individually so that light is transmitted or emitted. The driving circuit of the display device includes a data driver for applying data signals to data lines of the array of pixels, a gate driver for applying gate signals (or scanning signals) synchronized with the data signals sequentially to gate lines (scan lines) of the array of pixels, and a timing controller for controlling the data driver and the gate driver.

Recently, as display devices become thinner, technique to incorporate a gate driver into a display panel together with the array of pixels has been developed. The gate driver incorporated in the display panel is known as ‘GIP (Gate In Panel) circuit.’ In order to incorporate the gate driver in the display panel, it is necessary to simplify the configuration of the gate driver.

In particular, the gate driver includes a plurality of switching elements. As display devices are developed to have a higher resolution, the number of switching elements included the gate driver increases so as to apply gate signals to a plurality of gate lines. As the number of switching elements included in the gate driver increases, it is difficult to implement a narrow bezel of the display device having the gate driver incorporated into the display panel.

### SUMMARY

In view of the above, an object of the present disclosure is to provide a shift register including stages each implemented with only three transistors to thereby drastically reduce the number of switching elements included in a gate driver including the shift register.

Another object of the present disclosure is to provide a shift register that reduces the number of switching elements of a gate driver and the numbers of clock signals and voltage signals for driving the gate driver, and improves the design margin to increase the space in which the gate driver is disposed in the display panel, and a gate driver including the same.

It should be noted that objects of the present disclosure are not limited to the above-described objects, and other objects of the present disclosure will be apparent to those skilled in the art from the following descriptions.

According to an exemplary embodiment of the present disclosure, there is provided a gate driver for a display panel. The gate driver includes a shift register including a plurality of stages. The n^{th} stage (n is a positive integer) among the plurality of stages includes a buffer switching element having a gate electrode connected to a Q-node and a drain electrode to receive a first clock, a first switching element having a gate electrode to receive a second clock and a drain electrode to receive a start pulse, and a second switching element having a gate electrode to receive the second clock and a drain electrode to receive a gate high voltage (VGH), a first capacitor connected between the Q-node and a source electrode of the buffer switching element, and a second capacitor connected between the drain electrode of the first switching element and the Q-node. The high state of each of the first clock, the second clock and the start pulse is respectively equal to the gate high voltage, and the low state thereof is respectively equal to a gate low voltage (VGL). The number of switching elements included in the gate driver is drastically reduced, such that the numbers of clock signals and voltage signals required for driving the gate driver can be reduced.

According to another exemplary embodiment of the present disclosure, there is provided a shift register of a gate for a display panel. The shift register includes a plurality of stages. Each of the stages includes a buffer switching element to output a first clock according to a voltage of a Q-node, a first switching element to control the voltage of the Q-node according to a second clock, a second switching element to apply a gate high voltage to the output node according to the second clock, a first capacitor connected between the Q-node and at output node, and a second capacitor connected between the first switching element and the Q-node. The high state of each of the first clock and the second clock is respectively equal to the gate high voltage, and the low state thereof is respectively equal to a gate low voltage. The number of lines for delivering clock signals and voltage signals for driving the gate driver can be reduced, and the design margin can be improved to increase the space in which the gate driver is disposed in the display panel.

The details of one or more embodiments of the subject matter described in this specification are set forth in the accompanying drawings and the description below.

According to an exemplary embodiment of the present disclosure, the number of switching elements included in the gate driver is drastically reduced, such that the numbers of clock signals and voltage signals required for driving the gate driver can be reduced.

According to an exemplary embodiment of the present disclosure, the number of lines for delivering clock signals and voltage signals for driving the gate driver can be reduced, and the design margin can be improved to increase the space in which the gate driver is disposed in the display panel.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a block diagram of a display device including a gate driving circuit according to an exemplary embodiment of the present disclosure;

FIG. 2 is a block diagram of a shift register according to an exemplary embodiment of the present disclosure;

FIG. 3 is a circuit diagram showing a configuration of one of the plurality of stages in the shift register according to an exemplary embodiment of the present disclosure;

FIG. 4 is a waveform diagram showing input/output signals to/from the stage of the shift register shown in FIG. 3 according to an exemplary embodiment of the present disclosure;

FIGS. 5A to 5C are circuit diagrams illustrating signal flows at the stage of the shift register according to the waveform diagram shown in FIG. 4;

FIG. 6 is a circuit diagram showing a configuration of one of the plurality of stages in a shift register according to another exemplary embodiment of the present disclosure;

FIG. 7 is a waveform diagram showing input/output signals to/from the stage of the shift register shown in FIG. 3 according to another exemplary embodiment of the present disclosure; and

FIGS. 8A to 8C are circuit diagrams illustrating signal flows at the stage of the shift register according to the waveform diagram shown in FIG. 4.

### DETAILED DESCRIPTION OF THE PREFERRED EMBODIMENTS

Advantages and features of the present disclosure and methods to achieve them will become apparent from the descriptions of exemplary embodiments hereinbelow with reference to the accompanying drawings. However, the present disclosure is not limited to exemplary embodiments disclosed herein but may be implemented in various different ways. The exemplary embodiments are provided for making the disclosure of the present disclosure thorough and for fully conveying the scope of the present disclosure to those skilled in the art. It is to be noted that the scope of the present disclosure is defined only by the claims.

The figures, dimensions, ratios, angles, the numbers of elements given in the drawings are merely illustrative and are not limiting. Further, in describing the present disclosure, descriptions on well-known technologies may be omitted in order not to unnecessarily obscure the gist of the present disclosure. It is to be noticed that the terms “comprising,” “having,” “including” and so on, used in the description and claims, should not be interpreted as being restricted to the means listed thereafter unless specifically stated otherwise. Where an indefinite or definite article is used when referring to a singular noun, e.g. “a,” “an,” and “the,” this includes a plural of that noun unless specifically stated otherwise.

For elements having specific values, they are interpreted as including error margins even without explicit statements.

In describing positional relationship, such as “an element A on an element B,” “an element A above an element B,” “an element A below an element B,” and “an element A next to an element B,” another element C may be disposed between the elements A and B unless the term “directly” or “immediately” is explicitly used.

As used herein, a phrase “an element A on an element B” refers to that the element A may be disposed directly on the element B and/or the element A may be disposed indirectly on the element B via another element C.

The terms first, second and the like in the descriptions and in the claims are used for distinguishing between similar elements and not necessarily for describing a sequential or chronological order. Theses terms are used to merely distinguish one element from another. Accordingly, as used herein, a first element may be a second element within the technical idea of the present disclosure.

Like reference numerals denote like elements throughout the descriptions.

The drawings are not to scale and the relative dimensions of various elements in the drawings are depicted schematically and not necessarily to scale.

Features of various exemplary embodiments of the present disclosure may be combined partially or totally. As will be clearly appreciated by those skilled in the art, technically various interactions and operations are possible. Various exemplary embodiments can be practiced individually or in combination.

Herein, TFTs may be implemented as p-type or n-type transistors. In describing scan signals in the form of pulses, a gate high voltage VGH level is defined as “high state” while a gate low voltage VGL level is defined as “low state.”

Hereinafter, exemplary embodiments of the present disclosure will be described in detail with reference to the accompanying drawings.

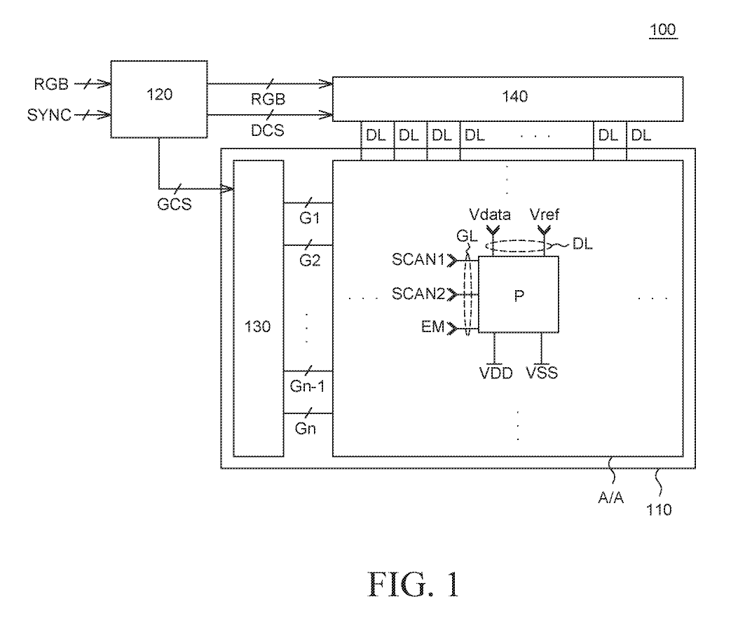

FIG. 1 is a block diagram of a display device including a gate driver according to an exemplary embodiment of the present disclosure. All the components of the display device according to all embodiments of the present disclosure are operatively coupled and configured.

Referring to FIG. 1, a display device 100 includes a display panel 110 including a plurality of pixels P, a gate driver 130 for applying gate signals to the plurality of pixels P, a data driver 140 for applying data signals to the plurality of pixels P, and a timing controller 120 for controlling the gate driver 130 and the data driver 140. The display device 100 may be either an organic light-emitting display (OLED) device or a liquid-crystal display (LCD) device, or may be of other types.

The timing controller 120 processes image data RGB input from an external source appropriately for the size and the resolution of the display panel 110 to supply it to the data driver 140. The timing controller 120 receives synchronization signals SYNC input from an external source such as a dot clock signal, a horizontal synchronization signal and a vertical synchronization signal, and generates gate control signals and data control signals by using them. The timing controller 120 applies the generated the gate control signals GCS and the data control signals DCS to the gate driver 130 and the data driver 140, respectively, to thereby control the gate driver 130 and the data driver 140.

The gate driver 130 applies the gate signals to the gate lines GL in response to the gate control signals GCS received from the timing controller 120. The gate signals includes at least one scan signal. Although the gate driver 130 is illustrated as being disposed on one side of the display panel 110 in FIG. 1, the number and location of the gate drivers 130 are not limited thereto. That is, the gate driver 130 may be disposed on one side or either side of the display panel 110 as a GIP (Gate In Panel).

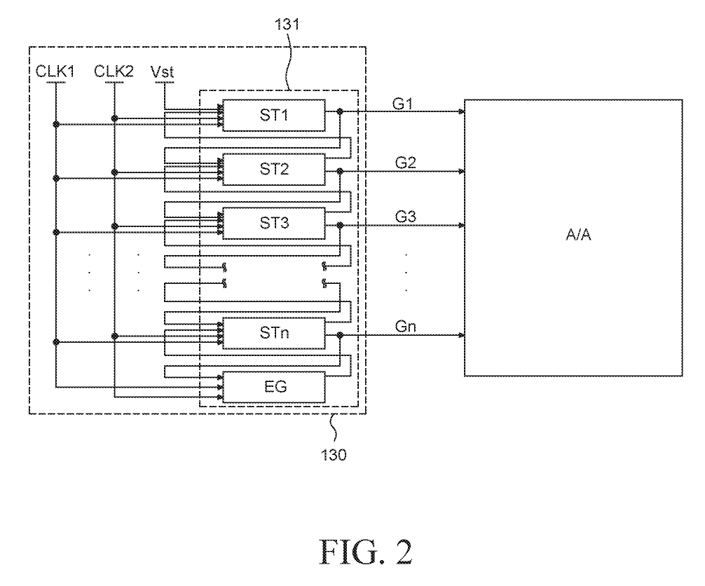

Referring to FIG. 1, the gate driver 130 is disposed on one side of an active area A/A in the display panel 110 and connected to the active area A/A through gate lines G1 to Gn. The gate driver 130 includes a plurality of stages. The stages output gate signals and provide the gate signals to the active area A/A through the gate lines G1 to Gn. The structure of the gate driver 130 will be described in more detail with reference to FIG. 2.

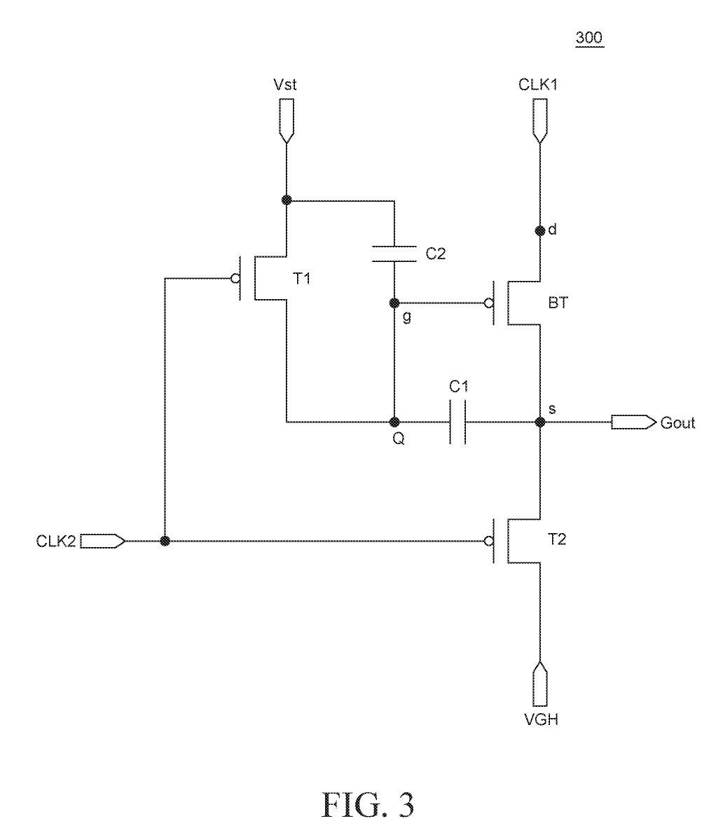

In addition, the gate driver 130 includes a shift register including a plurality of stages. Each of the plurality of stages in the shift register may include a plurality of switching elements. For example, one stage may include three switching elements, and accordingly two clock signals, a start pulse and a gate voltage may be applied to drive the shift register. The configuration of the stages in the shift register will be described in more detail with reference to FIG. 3.

The data driver 140 converts image data RGB into data voltage according to the data control signal DCS received from the timing controller 120 and applies the converted data voltage to the pixels P through the data lines DL.

A plurality of gate lines GL and a plurality of data lines DL intersect with one another in the display panel 110. Each of the plurality of pixels P is connected to the respective gate lines GL and the respective data lines DL. Specifically, one pixel P receives gate signals from the gate driver 130 through the gate lines GL and receives data signals from the data driver 140 through the data lines DL. Accordingly, one pixel P receives one or more scan signals through the gate lines GL and receives the data voltage Vdata and a reference voltage Vref through the data lines DL.

The display device 100 according to the exemplary embodiment of the present disclosure includes the gate driver 130 for driving the display panel 110 including the plurality of pixels P, the data driver 140, and the timing controller 120. The gate driver 130 includes a plurality of stages. Each of the plurality of stages in the shift register includes three switching elements and may be driven by a less number of clock signals and voltage signals. Accordingly, the gate driver 130 can drastically reduce the number of switching elements required for the shift register, so that the margin is improved to increase the space in which the gate driver 130 is disposed in the display device 100.

FIG. 2 is a block diagram of a gate driver according to an exemplary embodiment of the present disclosure. For convenience of illustration, description will be made with reference to FIG. 1.

Referring to FIG. 2, the gate driver 130 is disposed on one side of the active area A/A. The gate driver 130 includes a shift register 131 including a plurality of stages ST1 to STn, where n is a positive integer. Specifically, the shift register 131 includes the plurality of stages ST1 to STn that are cascaded. The configuration of one of the plurality of stages ST1 to STn in the shift register 131 will be described in more detail with reference to FIG. 3.

Referring to FIG. 2, the shift register 131 has a dummy stage that generates no output but provides a carry signal to another stage. Specifically, the shift register 131 includes the dummy stage EG next to the last stage STn. Specifically, the dummy stage EG is connected to the last stage STn that outputs the last gate signal, and the dummy stage EG provides a carry signal to the last stage STn without outputting any gate signal.

In the gate driver 130, the shift register 131 sequentially applies the gate signals to the active area A/A through the gate lines G1 to Gn. Specifically, the shift register 131 receives gate driver control signals GDC and generates gate signals. The gate driver control signals GDC include a gate start pulse (GSP) Vst and gate shift clocks (GSC) CLK1 and CLK2, etc. That is, the first clock CLK1, the second clock CLK2, the carry signal Gout Pre received from the previous stage or the start pulse Vst, and the gate high voltage VGH or the gate low voltage VGL are input to the shift register 131. The plurality of gate shift clocks CLK1 and CLK2 include the first clock CLK1 and the second clock CLK2.

Accordingly, the shift register 131 sequentially applies the gate signals generated in the plurality of stages ST1 to STn, respectively, to the gate lines G1 to Gn in response to the gate driver control signals GDC. Specifically, the stages ST1 to STn of the shift register 131 start to generate gate signals in response to the gate start pulse Vst, and shift and output the gate signals in response to the second clock signal CLK2. The gate signals output from the stages ST1 to STn, respectively, are transmitted to the gate lines G1 to Gn and are also input to the next stages as carry signals.

The gate driver according to the exemplary embodiment of the present disclosure includes the shift register 131 including the plurality of stages ST1 to STn. A variety of gate driver control signals GDC are input to each of the plurality of stages ST1 to STn to thereby shift the gate signals, and the stages ST1 to STn provide the shifted gate signals to the gate lines G1 to Gn. Thus, each of the plurality of stages ST1 to STn includes three switching elements and may be driven with the first clock CLK1, the second clock CLK2, and the gate start pulse Vst. In this manner, the gate driver 130 can reduce the number of clocks and gate driver control signals GDC required to drive the shift register 131, as well as the number of lines required to apply the clocks and gate driver control signals GDC. Moreover, as the number of lines connected to the gate driver 130 is reduced, the margin can be improved to increase the space in which the gate driver 130 is disposed in the display device 100. The circuit configuration of each of the plurality of stages ST1 to STn will be described in more detail with reference to FIG. 3.

FIG. 3 is a circuit diagram showing a configuration of one of the plurality of stages in the shift register according to an exemplary embodiment of the present disclosure. Descriptions will be made with reference to FIGS. 1 and 2 for convenience of illustration.

Referring to FIG. 3, a stage 300 includes a buffer switching element BT, a first switching element T1, a second switching element T2, a first capacitor C1, and a second capacitor C2. That is, the stage 300 includes three switching elements and two capacitors. The buffer switching element BT, the first switching element T1 and the second switching element T2 are PMOS TFTs (thin-film transistors). It is to be noted that the TFTs are merely illustrative and different kinds of switching elements may be used in other implementations.

Referring to FIG. 3, the buffer switching element BT has a gate electrode g connected to a Q-node, and a drain electrode d to receive the first clock CLK1. Specifically, the Q-node is connected to the gate electrode g of the buffer switching element BT, a first clock line via which the first clock CLK1 is input is connected to the drain electrode d of the buffer switching element BT, and an output node is connected to source electrode s of the buffer switching element BT.

Referring to FIG. 3, the first switching element T1 includes a gate electrode to receive the second clock CLK2, and a drain electrode to receive start pulse Vst. Specifically, a second clock line via which the second clock CLK2 is input is connected to the gate electrode of the first switching element T1, a gate start pulse line via which the gate start signal Vst is input to is connected to the drain electrode of the first switching element T1, and the Q-node is connected to the source electrode of the first switching element T1.

Referring to FIG. 3, the second switching element T2 includes a gate electrode to receive the second clock CLK2, and a drain electrode to receive the gate high voltage VGH. Specifically, a second clock line is connected to the gate electrode of the second switching element T2, a gate voltage line via which the gate high voltage VGH is input to is connected to the drain electrode of the second switching element T2, and the output node is connected to the source electrode of the second switching element T2.

Referring to FIG. 3, the first capacitor C1 is disposed between the Q-node and the source electrode s of the buffer switching element BT. The second capacitor C2 is disposed between the drain electrode of the first switching element T1 and the Q-node.

The first clock CLK1, the second clock CLK2, the start pulse Vst and the gate high voltage VGH are applied to the stage 300. Herein, each of the first clock CLK1, the second clock CLK2 and the start pulse Vst has a high state equal to the gate high voltage VGH level and a low state thereof equal to the gate low voltage VGL level. Accordingly, the buffer switching element BT, the first switching element T1 and the second switching element T2 are turned on with the gate low voltage VGL.

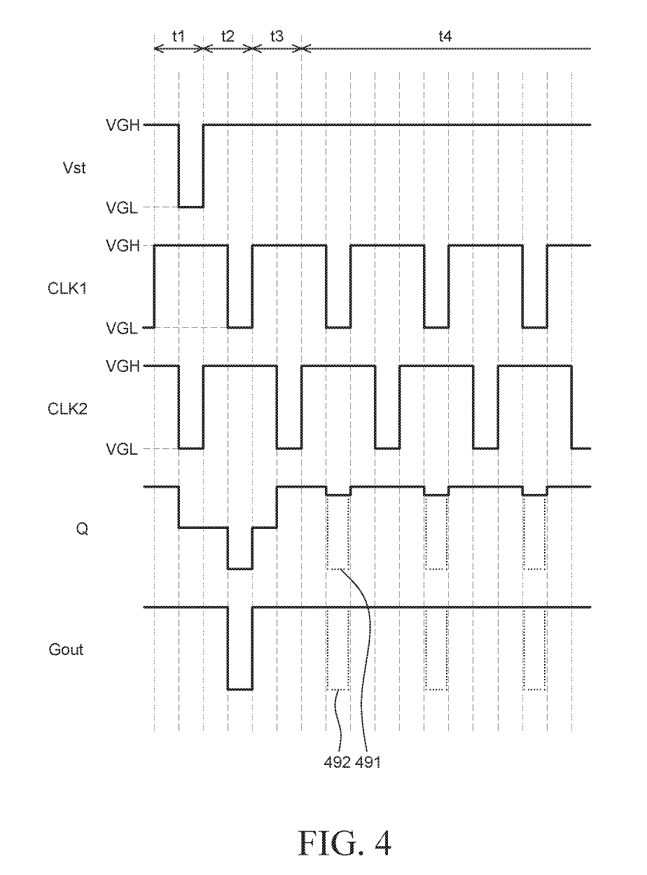

Accordingly, the buffer switching element BT outputs the first clock CLK1 at the output node in accordance with the voltage of the Q-node. The first switching element T1 controls the voltage of the Q-node according to the second clock CLK2. The second switching element T2 applies the gate high voltage VGH to the output node according to the second clock CLK2. In addition, the source electrode s of the buffer switching element BT and the source electrode of the second switching element T2 are connected to the output node of the stage 300. That is, the first clock CLK1 or the gate high voltage VGH may be output via the output node depending on the operation of the buffer switching element BT and the second switching element T2. The waveforms output from the buffer switching element BT upon receiving the input signals, for example, the first clock CLK1, the second clock CLK2, the start pulse Vst and the gate high voltage VGH, will be described below with reference to FIG. 4.

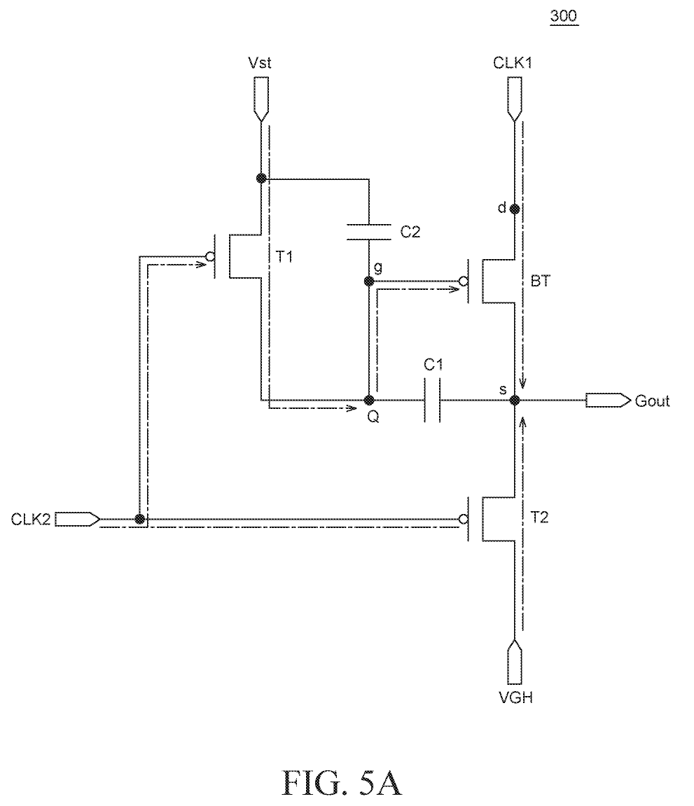

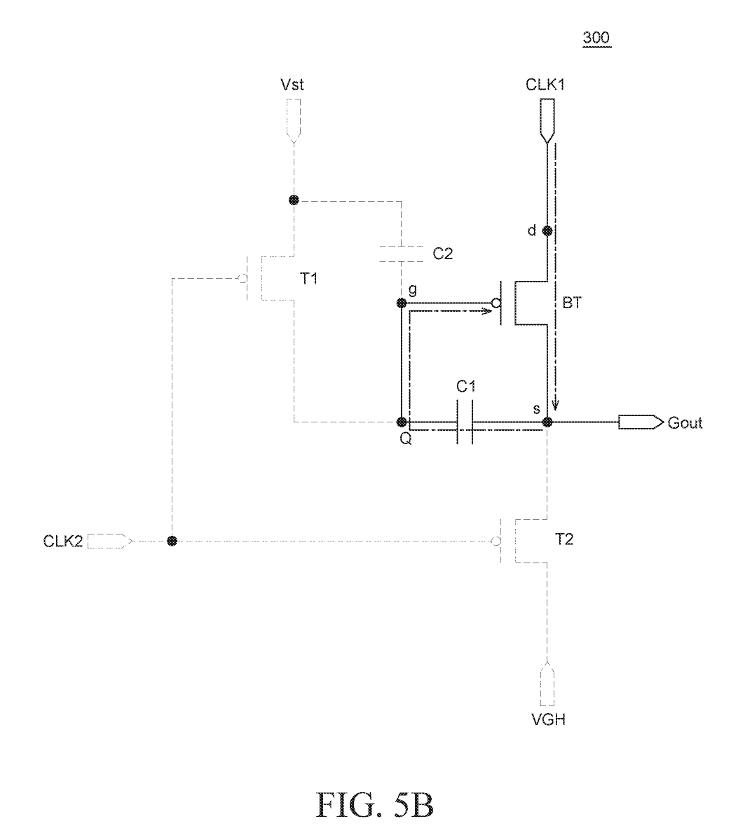

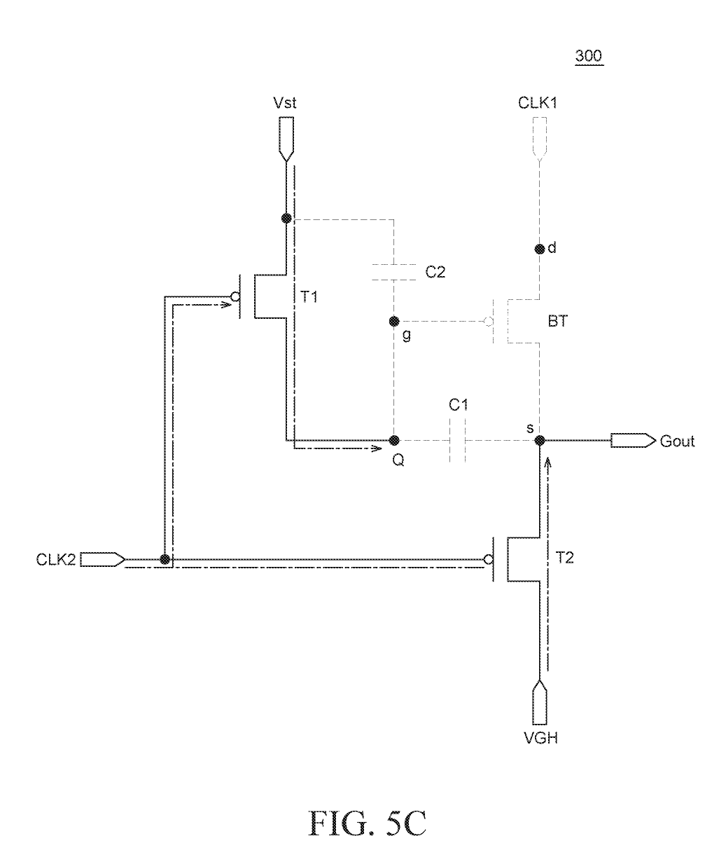

FIG. 4 is a waveform diagram showing input/output signals to/from the stage of the shift register shown in FIG. 3 according to an exemplary embodiment of the present disclosure. FIGS. 5A to 5C are circuit diagrams illustrating signal flows at the stage of the shift register according to the waveform diagram shown in FIG. 4. The circuit diagrams shown in FIGS. 5A to 5C illustrate signal flows during different period of times for different input/output signals. The circuit diagrams shown in FIGS. 5A to 5C include the elements identical to those of the circuit diagram shown in FIG. 3 and, therefore, the stage 300 will not be described to avoid redundancy. In FIGS. 5A to 5C, dash-dot lines indicate the flows of the internal signals by the signal inputted to the stage 300, and dashed lines indicate elements that are not activated by the signal inputted to the stage 300. Descriptions will be made with reference to FIGS. 1 and 2 for convenience of illustration.

Referring to FIG. 4, based on the pulse timings of the first clock CLK1, the second clock CLK2, the start pulse Vst and the gate high voltage VGH applied to the stage 300, the stage 300 operates in a first period of time t1, a second period of time t2, a third period of time t3, and a fourth period of time t4.

In the first period of time t1, a pulse of the start pulse Vst and a pulse of the second clock CLK2 having the amplitude of the gate low voltage VGL is input to the stage 300, and the first clock CLK1 is input to the stage at the gate high voltage VGH level.

In the second period of time t2, the start pulse Vst and the second clock CLK2 are input to the stage 300 at the gate low voltage VGL level, and a pulse of the first clock CLK1 having the amplitude of the gate high voltage VGH is input to the stage 300.

In the third period of time t3, the start pulse Vst and the first clock CLK1 are input to the stage 300 at the gate high voltage VGH level, and a pulse of the second clock CLK2 having the amplitude of the gate low voltage VGL is input to the stage 300.

In the fourth period of time t4, the start pulse Vst is input to the stage 300 at the gate high voltage VGH level, and pulses of the first clock CLK1 and pulses of the second clock CLK2 having the amplitude of the gate low voltage VGL are alternately input to the stage 300. That is, there is a phase difference between the first clock CLK1 and the second clock CLK2, which is a gate shift clock GSC.

Referring to FIGS. 4 and 5A, in the first period of time t1, as the pulse of the second clock CKL2 having the amplitude of the gate low voltage VGL is input to the stage 300, the first switching element T1 and the second switching element T2 are both turned on.

Accordingly, the start pulse Vst is input through the turned-on first switching element T1, and the voltage of the Q-node is dropped by the start pulse Vst. Further, the gate high voltage VGH is input through the turned-on second switching element T2, such that the voltage of the output node is held at the gate high voltage VGH. That is, in the first period of time t1, the voltage of the output node of the stage 300, which is connected to the source electrode s of the buffer switching element BT, is held at the high state. By doing so, the voltage of the output node can be held at the high state as the gate high voltage VGH is applied to the output node by the second clock CLK2, such that it is possible to avoid the voltage drop in the voltage of the output node due to the parasitic capacitance of the buffer switching element BT.

Referring to FIGS. 4 and 5A, in the first period t1, the voltage of the Q-node is dropped by the start pulse Vst applied through the turned-on first switching element T1, and accordingly the buffer switching element BT is also turned on.

As a result, the first clock CLK1 is applied from the first clock line connected to the drain electrode d of the buffer switching element BT through the turned-on buffer switching element BT. In the first period of time t1, the first clock CLK1 has the gate high voltage VGH, and thus the voltage of the output node is held at the gate high voltage VGH.

Subsequently, referring to FIGS. 4 and 5B, in the second period of time t2, the voltage of the Q-node has such a low level that the buffer switching element BT is turned on. Thus, the buffer switching element BT is turned on by the low voltage of the Q-node. On the other hand, as the second clock CLK2 is input at the gate high voltage VGH level in the second period of time t2, the first switching element T1 and the second switching element T2 are turned off.

As the buffer switching element BT is turned on in the second period of time t2, the first clock CLK1 is applied from the first clock line connected to the drain electrode d of the buffer switching element BT. Thus, the pulse of the first clock CLK1 having the amplitude of the gate low voltage VGL is applied to the output node of the stage 300.

As such, when the first clock CLK1 is input at the low state while the voltage of the Q-node is the low state, the first capacitor C1 bootstraps the voltage of the Q-node and the voltage of the output node of the stage 300 connected to source electrode s of the buffer switching element BT. Specifically, when a pulse of the first clock CLK1 having the amplitude of the gate low voltage VGL is applied to the output node of the stage 300, the voltage of the Q-node is also dropped by the coupling of the first capacitor C1. As such, when the voltage of the gate electrode and the voltage of the source electrode of a switching element is raised or dropped together by a capacitor, it is referred to as bootstrapping.

Accordingly, the voltage of the gate electrode g and the voltage of the source electrode s of the buffer switching element BT are bootstrapped, so that the voltage difference Vgs between the gate electrode g and the source electrode s of the buffer switching element BT can be maintained. In this manner, the voltage difference Vgs can be maintained due to the bootstrapping by the first capacitor C1 in the second period of time t2, such that the buffer switching element BT can remain turned on.

As the buffer switching element BT remains turned on in the second period of time t2, the first clock CLK1 received at the drain electrode d of the buffer switching element BT can be output as it is through the output node of the stage 300 in the second period of time t2. That is, in the second period of time t2, the first clock CLK1 can be output as a gate signal to the gate line connected to the stage 300.

Subsequently, referring to FIGS. 4 and 5C, in the third period of time t3, a pulse of the second clock CKL2 having the amplitude of the gate low voltage VGL is input to the stage 300, such that the first switching element T1 and the second switching element T2 both are turned on. On the other hand, the start pulse Vst at the gate high voltage VGH level is applied.

Accordingly, the start pulse Vst is input through the turned-on first switching element T1, and the voltage of the Q-node is raised by the start pulse Vst at the gate high voltage VGH level. Further, the gate high voltage VGH is input through the turned-on second switching element T2, such that the voltage of the output node is changed to the gate high voltage VGH. That is, in the third period of time t3, the voltage of the output node of the stage 300, which is connected to the source electrode s of the buffer switching element BT, is changed to the high state.

As such, the gate high voltage VGH is applied to the Q-node through the first switching element T1 in the third period of time t3, such that the buffer switching element BT is turned off and the gate high voltage VGH is applied to the output node through the turned-on second switching element T2. In this manner, the voltage of the output node is changed back to the gate high voltage VGH after the first clock CLK1 is output as the gate signal in the second period of time t2, and accordingly the stage 300 can control so that the gate signal is output only in a particular period and not in other periods.

Subsequently, referring to FIGS. 4 and 5B, in the fourth period of time t4, only the pulse of the first clock CLK1 having the amplitude of the gate low voltage VGL is input to the stage 600, and the voltage of the Q-node has such a high level that the buffer switching element BT is turned off. Thus, the buffer switching element BT is turned off by the high voltage of the Q-node.

Incidentally, if the stage 300 does not include the second capacitor C2, the voltage of the Q-node may be synchronized with the first clock CLK1 in the fourth period of time t4, such that noise 491 may occur as shown in FIG. 4. The noise 491 at the Q-node has such a low voltage that the buffer switching element BT is turned on. The noise 491 at the Q-node may be a ripple generated as the buffer switching element BT is affected by the first clock CLK1.

Moreover, the noise 491 at the Q-node may have such a low voltage that the buffer switching element BT is turned on, and accordingly the first clock CLK1 may be applied to the output node while the buffer switching element BT is turned on. That is, the buffer switching element BT may be turned on by the noise 491 at the Q-node, and the stage 300 may generate noise voltage 492 at the output node synchronized with the first clock CLK1, such that a plurality of gate signals synchronized with the first clock CLK1 by the noise voltage 492 at the output node may be output in the fourth period of time t4.

In order to solve the above-described issues, the stage 300 includes the second capacitor 300. The second capacitor C2 in the stage 300 can suppress the ripple due to the first clock CLK1 input to the buffer switching element BT when the first clock CLK1 is input at the low state. That is, when the pulse of the first clock CLK1 having the amplitude of the gate low voltage VGL is input in the fourth period t4, the second capacitor C2 can avoid that the voltage of the Q-node is dropped by the noise 491 at the Q-node such that the buffer switching element BT is turned on. Furthermore, as the noise 491 at the Q-node can be suppressed by the second capacitor C2, the buffer switching element BT can remain turned off. As a result, the first clock CLK1 cannot generate the noise voltage 492 at the output node through the buffer switching element BT, and the gate signal is output only in the second period of time t2.

The stage 300 according to the exemplary embodiment of the present disclosure includes three switching elements and two capacitors, so that the number of switching elements required for sequentially outputting gate signals can be drastically reduced. Further, as the stage 300 includes three switching elements, two clocks CLK1 and CLK2 and one gate high voltage VGH are enough to drive the three switching elements in four different period of time, i.e., the first to fourth period of time t1 to t4. That is, the number of signals required for driving the gate driver 130 including the stage 300 is also reduced, and the number of lines for applying the clock signals and the gate voltage can be drastically reduced.

As a result, the numbers of switching elements, capacitors and lines required for the stage 300 and the gate driver 130 are drastically reduced, and accordingly the design margin can be improved to increase the space in which the gate driving circuit 130 is disposed in the display device 100.

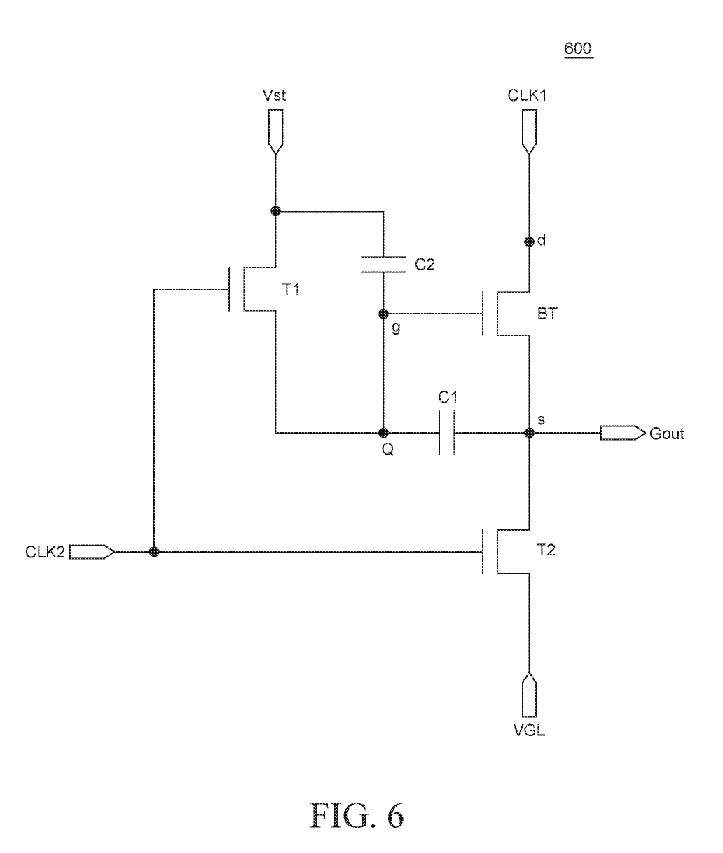

FIG. 6 is a circuit diagram showing a configuration of one of the plurality of stages in a shift register according to another exemplary embodiment of the present disclosure. FIG. 6 is substantially identical to the circuit diagram shown in FIG. 3 except that the switching elements are replaced with NMOS TFTs. Therefore, a stage 600 and signal flows in response to input/output signals will not be described to avoid redundancy. Descriptions will be made with reference to FIGS. 1 and 2 for convenience of illustration.

Referring to FIG. 6, in a stage 600, a buffer switching element BT, a first switching element T1 and a second switching element T2 are NMOS TFTs. It is to be noted that the TFTs are merely illustrative and different kinds of switching elements may be used in other implementations.

Referring to FIG. 6, the second switching element T2 includes a gate electrode to receive a second clock CLK2, and a drain electrode to receive a gate low voltage VGL. Specifically, a second clock line is connected to the gate electrode of the second switching element T2, a gate voltage line via which the gate low voltage VGL is input is connected to the drain electrode of the second switching element T2, and the output node is connected to the source electrode of the second switching element T2.

The first clock CLK1, the second clock CLK2, the start pulse Vst and the gate low voltage VGL are applied to the stage 600. Here, each of the first clock CLK1, the second clock CLK2 and the start pulse Vst has a high state equal to the gate high voltage VGH level and a low state equal to the gate low voltage VGL level. Accordingly, the buffer switching element BT, the first switching element T1 and the second switching element T2 are turned on with the gate high voltage VGH.

Accordingly, the buffer switching element BT outputs the first clock CLK1 at the output node in accordance with the voltage of the Q node. The first switching element T1 controls the voltage of the node Q according to the second clock CLK2. The second switching element T2 applies the gate low voltage VGL to the output node according to the second clock CLK2. In addition, the source electrode s of the buffer switching element BT and the source electrode of the second switching element T2 are connected to the output node of the stage 600. That is, the first clock CLK1 or the gate low voltage VGL may be output via the output node depending on the operation of the buffer switching element BT and the second switching element T2.

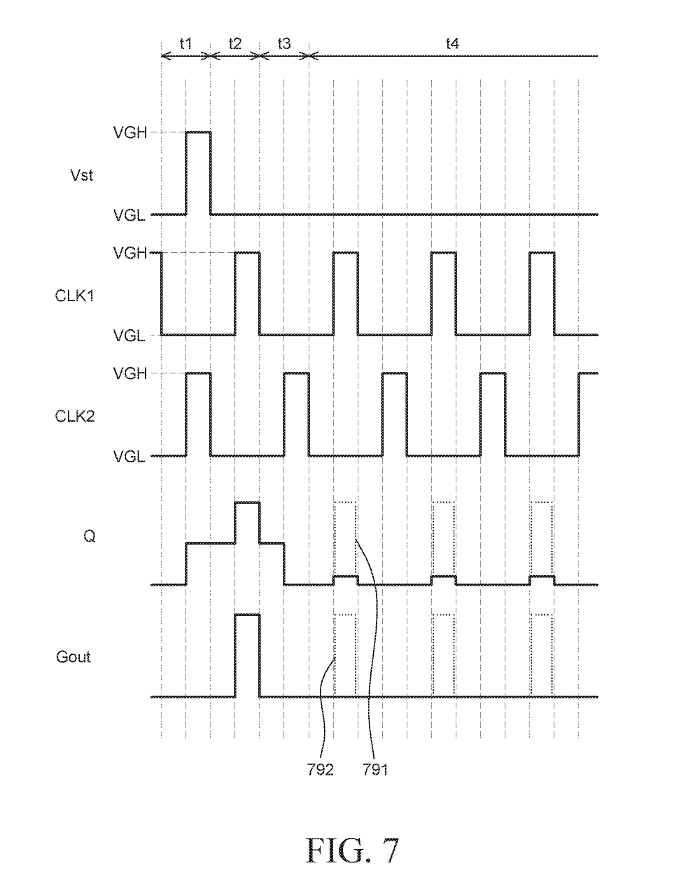

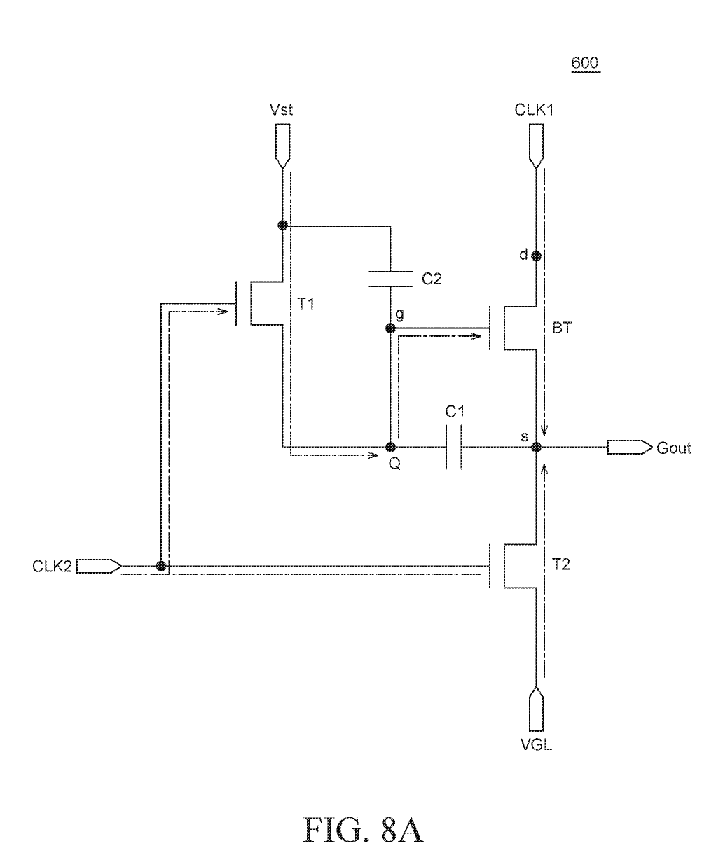

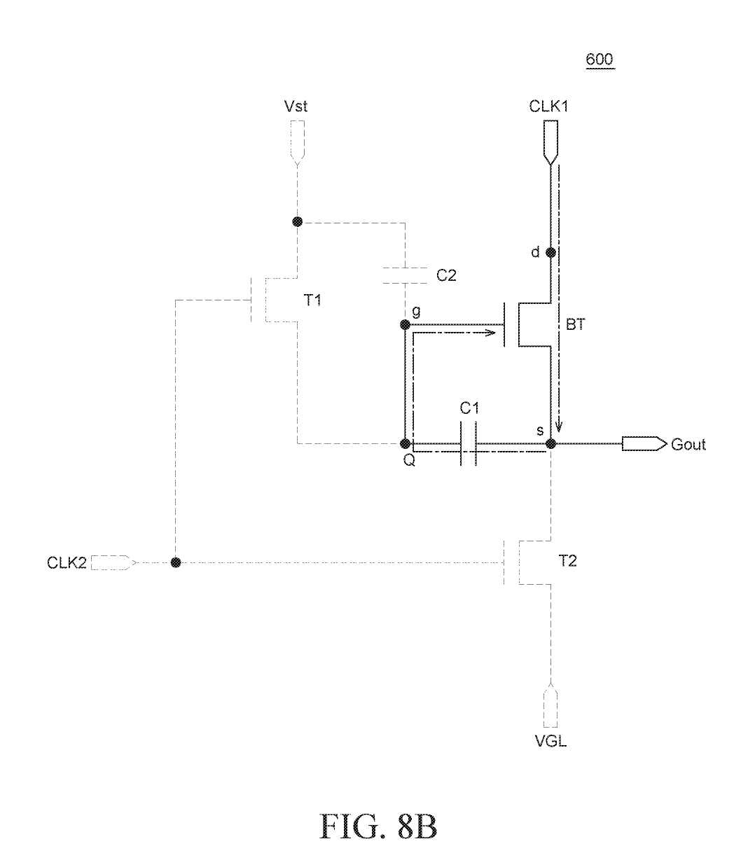

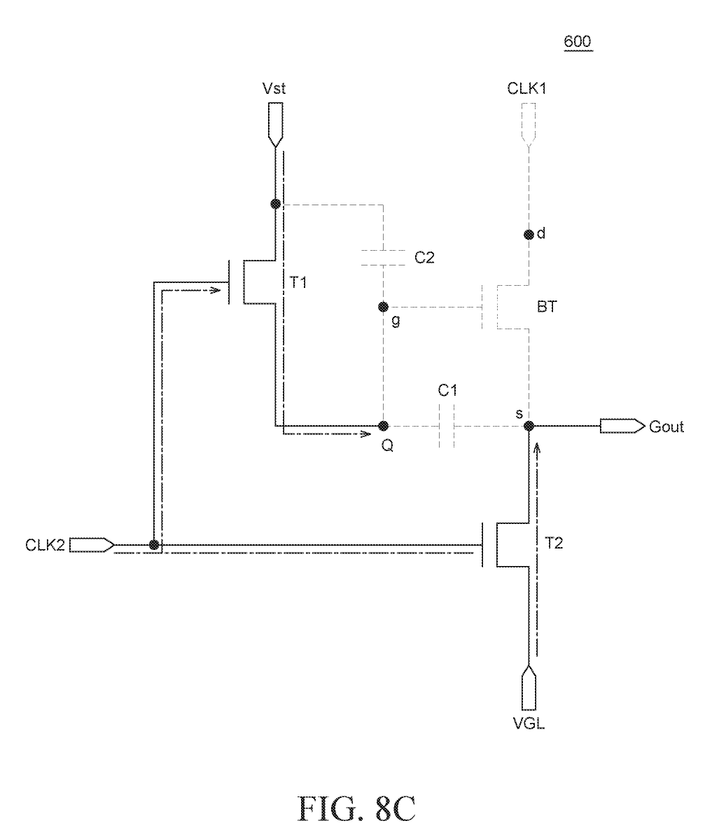

FIG. 7 is a waveform diagram showing input/output signals to/from the stage of the shift register shown in FIG. 3 according to another exemplary embodiment of the present disclosure. FIGS. 8A to 8C are circuit diagrams illustrating signal flows at the stage of the shift register according to the waveform diagram shown in FIG. 4. FIG. 7 is substantially identical to the waveform diagram shown in FIG. 4 except for the input/output voltages. Therefore, the driving characteristics of the stage 600 in response to the signals will not be described to avoid redundancy. The circuit diagrams shown in FIGS. 8A to 8C illustrate signal flows during different period of times for different input/output signals. The circuit diagrams shown in FIGS. 8A to 8C include the elements identical to those of the circuit diagram shown in FIG. 6. Therefore, the stage 600 will not be described to avoid redundancy. In FIGS. 8A to 8C, dash-dot lines indicate the flows of the internal signals by the signal inputted to the stage 600, and dashed lines indicate elements that are not activated by the signal inputted to the stage 600. Descriptions will be made with reference to FIGS. 1 and 2 for convenience of illustration.

Referring to FIG. 7, in the first period of time t1, a pulse of the start pulse Vst and that of the second clock CLK2 having the amplitude of the gate high voltage VGH are input to the stage 600, and the first clock CLK1 at the gate low voltage VGL level is input to the stage 600. In the second period of time t2, the start pulse Vst and the second clock CLK2 at the gate low voltage VGL level are input to the stage 600, and a pulse of the first clock CLK1 having the amplitude of the gate high voltage VGH is input to the stage 600. In the third period of time t3, the start pulse Vst and the first clock CLK1 at the gate low voltage VGL level are input to the stage 600, and a pulse of the second clock CLK2 having the amplitude of the gate high voltage VGH is input to the stage 600. In the fourth period of time t4, the start pulse Vst is input to the stage 600 at the gate low voltage VGL level, and pulses of the first clock CLK1 and pulses of the second clock CLK2 having the amplitude of the gate high voltage VGH are alternately input to the stage 300. That is, there is a phase difference between the first clock CLK1 and the second clock CLK2, which is the gate shift clock GSC.

Referring to FIGS. 7 and 8A, in the first period of time t1, as the pulse of the second clock CKL2 having the amplitude of the gate high voltage VGH is input to the stage 600, the first switching element T1 and the second switching element T2 both are turned on.

As a result, the start pulse Vst is input through the turned-on first switching element T1, and the voltage of the Q-node is raised by the start pulse Vst. Further, the gate low voltage VGL is input through the turned-on second switching element T2, such that the voltage of the output node is held at the gate low voltage VGL. That is, in the first period of time t1, the voltage of the output node of the stage 600, which is connected to the source electrode s of the buffer switching element BT, is held at the low state. By doing so, the voltage of the output node can be held at the low state as the gate low voltage VGL is applied to the output node by the second clock CLK2, such that it is possible to avoid the voltage drop in the voltage of the output node due to the parasitic capacitance of the buffer switching element BT.

Referring to FIGS. 7 and 8A, in the first period of time t1, the voltage of the Q-node is raised by the start pulse Vst applied through the turned-on first switching element T1, and accordingly the buffer switching element BT is also turned on.

As a result, the first clock CLK1 is applied from the first clock line connected to the drain electrode d of the buffer switching element BT through the turned-on buffer switching element BT. In the first period of time t1, the first clock CLK1 has the gate low voltage VGL, and thus the voltage of the output node is held at the gate low voltage VGL.

Subsequently, referring to FIGS. 7 and 8B, in the second period of time t2, the voltage of the Q-node has such a high level that the buffer switching element BT is turned on. Thus, the buffer switching element BT is turned on by the high voltage of the Q-node. On the other hand, as the second clock CLK2 is input at the gate high voltage VGH level in the second period of time t2, the first switching element T1 and the second switching element T2 are turned off.

As the buffer switching element BT is turned on in the second period of time t2, the first clock CLK1 is applied from the first clock line connected to the drain electrode d of the buffer switching element BT. Thus, the pulse of the first clock CLK1 having the amplitude of the gate high voltage VGL is applied to the output node of the stage 600.

As such, when the first clock CLK1 is input at the high state while the voltage of the Q-node is the high state, the first capacitor C1 bootstraps the voltage of the Q-node and the voltage of the output node of the stage 600 connected to source electrode s of the buffer switching element BT. Specifically, when a pulse of the first clock CLK1 having the amplitude of the gate high voltage VGH is applied to the output node of the stage 600, the voltage of the Q-node is also raised by the coupling of the first capacitor C1.

Accordingly, the voltage of the gate electrode g and the voltage of the source electrode s of the buffer switching element BT are bootstrapped, so that the voltage difference Vgs between the gate electrode g and the source electrode s of the buffer switching element BT can be maintained. In this manner, the voltage difference Vgs can be maintained due to the bootstrapping by the first capacitor C1 in the second period of time t2, such that the buffer switching element BT can remain turned on.

Accordingly, in the second period of time t2, the first clock CLK1 received at the drain electrode d of the buffer switching element BT can be output as it is through the output node of the stage 300, such that the first clock CLK1 connected to the stage 600 can be output as a gate signal in the second period of time t2.

Subsequently, referring to FIGS. 7 and 8C, in the third period of time t3, a pulse of the second clock CKL2 having the amplitude of the gate high voltage VGH is input to the stage 600, such that the first switching element T1 and the second switching element T2 both are turned on. On the other hand, the start pulse Vst at the gate low voltage VGL level is applied.

Accordingly, the start pulse Vst is input through the turned-on first switching element T1, and the voltage of the Q-node is dropped by the start pulse Vst at the gate high low VGL level. Further, the gate low voltage VGL is input through the turned-on second switching element T2, such that the voltage of the output node is changed to the gate low voltage VGL. That is, in the third period of time t3, the voltage of the output node of the stage 600, which is connected to the source electrode s of the buffer switching element BT, is changed to the low state.

As such, the gate low voltage VGL is applied to the Q-node through the first switching element T1 in the third period of time t3, such that the buffer switching element BT is turned off and the gate low voltage VGL is applied to the output node through the turned-on second switching element T2. In this manner, the voltage of the output node is changed back to the gate low voltage VGL after the first clock CLK1 is output as the gate signal in the second period of time t2, and accordingly the stage 600 can control so that the gate signal is output only in a particular period and not in other periods.

Subsequently, referring to FIGS. 7 and 8B, in the fourth period of time t4, only the pulse of the first clock CLK1 having the amplitude of the gate high voltage VGH is input to the stage 600, and the voltage of the Q-node has such a low level that the buffer switching element BT is turned off. Thus, the buffer switching element BT is turned on by the low voltage of the Q-node.

Incidentally, if the stage 600 does not include the second capacitor C2, the voltage of the Q-node may be synchronized with the first clock CLK1 in the fourth period of time t4, such that noise 791 may occur as shown in FIG. 7. The noise 791 at the Q node has such a high voltage that the buffer switching element BT is turned on. The noise 791 at the Q-node may be a ripple generated as the buffer switching element BT is affected by the first clock CLK1.

Moreover, the noise 791 at the Q-node may have such a high voltage that the buffer switching element BT is turned on, and accordingly the first clock CLK1 may be applied to the output node while the buffer switching element BT is turned on. That is, the buffer switching element BT may be turned on by the noise 791 at the Q-node, and the stage 600 may generate noise voltage 792 at the output node synchronized with the first clock CLK1, such that a plurality of gate signals synchronized with the first clock CLK1 by the noise voltage 792 at the output node may be output in the fourth period of time t4.

In order to solve the above-described issues, the stage 600 includes the second capacitor 300. The second capacitor C2 in the stage 600 can suppress the ripple due to the first clock CLK1 input to the buffer switching element BT when the first clock CLK1 is input at the high state. That is, when the pulse of the first clock CLK1 having the amplitude of to the gate high voltage VGH is input in the fourth period t4, the second capacitor C2 can avoid that the voltage of the Q node is raised by the noise 791 at the Q node such that the buffer switching element BT is turned on. Furthermore, as the noise 791 at the Q-node can be suppressed by the second capacitor C2, the buffer switching element BT can remain turned off. As a result, the first clock CLK1 cannot generate the noise voltage 792 at the output node through the buffer switching element BT, and the gate signal is output only in the second period of time t2.

The stage 600 according to the exemplary embodiment of the present disclosure includes three switching elements and two capacitors, so that the number of switching elements required for sequentially outputting gate signals can be drastically reduced. Further, as the stage 600 includes three switching elements, two clocks CLK1 and CLK2 and one gate low voltage VGL are enough to drive the three switching elements in four different period of time, i.e., the first to fourth period of time t1 to t4. That is, the number of signals required for driving the gate driver 130 including the stage 600 is also reduced, and the number of lines for applying the clock signals and the gate voltage can be drastically reduced.

As a result, the numbers of switching elements, capacitors and lines required for the stage 600 and the gate driver 130 are drastically reduced, and accordingly the design margin can be improved to increase the space in which the gate driving circuit 130 is disposed in the display device 100.

In the above examples, the shift register in the gate driver 130 includes the plurality of stages, where each of the stages can be the stage illustrated in FIGS. 3-8C.

The exemplary embodiments of the present disclosure can also be described as follows:

According to an aspect of the present disclosure, there is provided a gate driver. The gate driver includes a shift register including a plurality of stages. The n^{th} stage (n is a positive integer) among the plurality of stages includes a buffer switching element having a gate electrode connected to a Q-node and a drain electrode to receive a first clock, a first switching element having a gate electrode to receive a second clock and a drain electrode to receive a start pulse, and a second switching element having a gate electrode to receive the second clock and a drain electrode to receive a gate high voltage (VGH), a first capacitor connected between the Q-node and a source electrode of the buffer switching element, and a second capacitor connected between the drain electrode of the first switching element and the Q-node. The high state of each of the first clock, the second clock and the start pulse is respectively equal to the gate high voltage, and the low state thereof is respectively equal to a gate low voltage (VGL). The number of switching elements included in the gate driver is drastically reduced, such that the numbers of clock signals and voltage signals required for driving the gate driver can be reduced.

The source electrode of the buffer switching element and the source electrode of the second switching element may be connected to the output node of the n^{th} stage.

The buffer switching element, the first switching element and the second switching element may be PMOS transistors

When the first clock is input at the low state while a voltage of the Q-node is at the low state, the first capacitor may bootstrap the voltage of the Q-node and a voltage of the output node of the n^{th} stage connected to the source electrode of the buffer switching element.

The second capacitor may suppress a ripple by the first clock input to the buffer switching element when the first clock is input at the low state.

The second switching element may hold the voltage of the output node of the n^{th} stage connected to the source electrode of the buffer switching element at the high state.

The buffer switching element, the first switching element and the second switching element may be NMOS transistors

When the first clock is input at the high state while a voltage of the Q-node is at the high state, the first capacitor may bootstrap the voltage of the Q-node and a voltage of the output node of the n^{th} stage connected to the source electrode of the buffer switching element.

The second capacitor may suppress a ripple by the first clock input to the buffer switching element when the first clock is input at the high state.

The second switching element may hold the voltage of the output node of the n^{th} stage connected to the source electrode of the buffer switching element at the high state.

According to another aspect of the present disclosure, there is provided a shift register. The shift register includes a plurality of stages. Each of the stages includes a buffer switching element to output a first clock according to a voltage of a Q-node, a first switching element to control the voltage of the Q-node according to a second clock, a second switching element to apply a gate high voltage to the output node according to the second clock, a first capacitor connected between the Q-node and at output node, and a second capacitor connected between the first switching element and the Q-node. The high state of each of the first clock and the second clock is respectively equal to the gate high voltage, and the low state thereof is respectively equal to a gate low voltage. The number of lines for delivering clock signals and voltage signals for driving the gate driver can be reduced, and the design margin can be improved to increase the space in which the gate driver is disposed in the display panel.

The source electrode of the buffer switching element and the source electrode of the second switching element may be connected to the output node.

The buffer switching element, the first switching element and the second switching element may be PMOS transistors

The buffer switching element, the first switching element and the second switching element may be NMOS transistors

Thus far, exemplary embodiments of the present disclosure have been described in detail with reference to the accompanying drawings. However, the present disclosure is not limited to the exemplary embodiments, and modifications and variations can be made thereto without departing from the technical idea of the present disclosure. Accordingly, the exemplary embodiments described herein are merely illustrative and are not intended to limit the scope of the present disclosure. The technical idea of the present disclosure is not limited by the exemplary embodiments. The scope of protection sought by the present disclosure is defined by the appended claims and all equivalents thereof are construed to be within the true scope of the present disclosure.

What is claimed is:

1. A gate driver comprising:
a shift register comprising a plurality of stages,
wherein an n^{th} stage among the plurality of stages comprises:
a buffer switching element having a gate electrode connected to a Q-node and a drain electrode to receive a first clock signal;
a first switching element having a gate electrode to receive a second clock signal and a drain electrode to receive a start pulse;
a second switching element having a gate electrode to receive the second clock signal and a drain electrode to receive a gate high voltage;
a first capacitor connected between the Q-node and a source electrode of the buffer switching element; and
a second capacitor connected between the drain electrode of the first switching element and the Q-node,
wherein n is a positive integer, and
wherein a high state of each of the first clock signal, the second clock signal and the start pulse is respectively equal to the gate high voltage, and a low state thereof is respectively equal to a gate low voltage.

2. The gate driver of claim 1, wherein the source electrode of the buffer switching element and a source electrode of the second switching element are connected to an output node of the n^{th} stage.

3. The gate driver of claim 1, wherein the buffer switching element, the first switching element and the second switching element are PMOS transistors.

4. The gate driver of claim 3, wherein when the first clock signal is input at the low state while a voltage of the Q-node is at the low state, the first capacitor bootstraps the voltage of the Q-node and a voltage of the output node of the n^{th} stage connected to the source electrode of the buffer switching element.

5. The gate driver of claim 3, wherein the second capacitor suppresses a ripple by the first clock signal input to the buffer switching element when the first clock signal is input at the low state.

6. The gate driver of claim 3, wherein the second switching element holds the voltage of the output node of the n^{th} stage connected to the source electrode of the buffer switching element at the high state.

7. The gate driver of claim 1, wherein the buffer switching element, the first switching element and the second switching element are NMOS transistors.

8. The gate driver of claim 7, wherein when the first clock signal is input at the high state while a voltage of the Q-node is at the high state, the first capacitor bootstraps the voltage of the Q-node and a voltage of the output node of the n^{th} stage connected to the source electrode of the buffer switching element.

9. The gate driver of claim 7, wherein the second capacitor suppresses a ripple by the first clock signal input to the buffer switching element when the first clock signal is input at the high state.

10. The gate driver of claim 7, wherein the second switching element holds the voltage of the output node of the n^{th} stage connected to the source electrode of the buffer switching element at the high state.

11. A display device comprising:
a display panel including a plurality of pixels for display images;
the gate driver of claim 1 for applying gate signals to the plurality of pixels;
a data driver for applying data signals to the plurality of pixels; and
a timing controller for controlling the gate driver and the data driver.

12. A shift register comprising:
a plurality of stages, wherein each of the stages comprises:
a buffer switching element to output a first clock signal according to a voltage of a Q-node;
a first switching element to control the voltage of the Q-node according to a second clock signal;
a second switching element to apply a gate high voltage to the output node according to the second clock signal;
a first capacitor connected between the Q-node and at output node; and
a second capacitor connected between the first switching element and the Q-node,
wherein a high state of each of the first clock signal and the second clock signal is respectively equal to the gate high voltage, and a low state thereof is respectively equal to a gate low voltage.

13. The shift register of claim 12, wherein a source electrode of the buffer switching element and a source electrode of the second switching element are connected to the output node.

14. The shift register of claim 12, wherein the buffer switching element, the first switching element and the second switching element are PMOS transistors.

15. The shift register of claim 12, wherein the buffer switching element, the first switching element and the second switching element are NMOS transistors.

16. A display device comprising:
a display panel including a plurality of pixels for display images;
a gate driver for applying gate signals to the plurality of pixels, the gate driver including the shift register of claim 1;
a data driver for applying data signals to the plurality of pixels; and
a timing controller for controlling the gate driver and the data driver.
